(19) United States
(12) Patent Application Publication
(10) Pub. No.: US 2026/0189198 A1
(43) Pub. Date: Jul. 2, 2026

(54) TRANSFORMATION MODULE FOR AN RF AMPLIFIER ARRANGEMENT, RF AMPLIFIER ARRANGEMENT COMPRISING SUCH A TRANSFORMATION MODULE, AND ARRANGEMENT FOR ACCELERATING PARTICLES COMPRISING AT LEAST ONE SUCH RF AMPLIFIER ARRANGEMENT

(71) Applicant: TRUMPF Hüttinger GmbH + Co. KG, Freiburg (DE)

(72) Inventor: Felix Baum, Karlsruhe (DE)

(21) Appl. No.: 19/547,737

(22) Filed: Feb. 24, 2026

Related U.S. Application Data
(63) Continuation of application No. PCT/EP2024/074224, filed on Sep. 28, 2024.

(30) Foreign Application Priority Data
Aug. 30, 2023 (DE) 10 2023 123 366.1

(51) Int. Cl. H03F 1/56; H03F 3/26; H05H 7/02

(52) U.S. Cl. CPC H03F 1/56; H03F 3/265; H05H 7/02; H03F 2200/451; H05H 2007/025

(57) ABSTRACT

A transformation module for transforming a first input impedance at a first transformation module terminal to a second input impedance at a second transformation module terminal for use in an RF push-pull amplifier arrangement, wherein the transformation module has a multi-ply structure. The transformation module includes a multi-ply planar substrate including a circuit board, having a first outer ply, a second outer ply and a first intermediate ply which is arranged between the first and second outer plies. The transformation module further includes an outer conductor having a first outer conductor layer and a second outer conductor layer arranged on or in the multi-ply planar substrate. The first outer conductor layer is arranged in the form of a first planar outer conductor winding having a first and second end on or in the first outer ply.

### CROSS REFERENCE TO RELATED APPLICATIONS

This application is a continuation of International Application No. PCT/EP 2024/074224 (WO2025/046034A1 ), filed on Aug. 29, 2024, and claims benefit to German Patent Application No. DE 10 2023 123 366.1, filed on Aug. 30, 2023. The aforementioned applications are hereby incorporated by reference herein.

### FIELD

The invention relates to a transformation module for an RF amplifier arrangement, an RF amplifier arrangement having such a transformation module and an arrangement for accelerating particles.

### BACKGROUND

Inductive transformers are frequently used in high-frequency applications for matching input impedance. This allows, for example, a wider bandwidth matching to be achieved with an amplifier. An inductive transformer changes the input impedance by a factor that results from its number of turns. Typical factors are, for example, 1:4 or 1:9. Ferrites are used for low frequencies, in particular less than 100 MHz or less than 40 MHz. Microstrip structures are usually used in transformers for higher frequencies, in particular above 200 MHz or above 400 MHz.

The frequency ranges in between pose a challenge for such impedance transformers. This includes, in particular, frequencies between 40 MHz and 400 MHz, and more specifically, frequencies between 100 MHz and 200 MHz.

Ferrites do not function adequately in these frequency ranges, and pure microstrip structures are too large.

Currently, impedance transformers in the above-mentioned frequency range are usually implemented as bent coaxial cables having outer conductors which are electrically connected. Such an inductive impedance transformer is expensive to manufacture and complex to assemble. Furthermore, manufacturing tolerances are high in bent coaxial cables, which can lead to parasitic effects. Often, such inductive impedance transformers need to be manually adjusted after manufacturing, which is an enormous undertaking. Additionally, inductive impedance transformers, which are implemented using coaxial cables, take up a lot of space. Particularly in applications for particle acceleration, very high demands are placed on reliability. Furthermore, the very high power requirements often necessitate a very large number of RF amplifier arrangements, which must perform the same function reproducibly. Components with a large amount of manual labor in their manufacture are disadvantageous in this regard.

### SUMMARY

In an embodiment, the present disclosure provides a transformation module for transforming a first input impedance at a first transformation module terminal to a second input impedance at a second transformation module terminal for use in an RF push-pull amplifier arrangement, wherein the transformation module has a multi-ply structure. The transformation module comprises a multi-ply planar substrate including a circuit board, having a first outer ply, a second outer ply and a first intermediate ply which is arranged between the first and second outer plies. The transformation module further comprises an outer conductor having a first outer conductor layer and a second outer conductor layer arranged on or in the multi-ply planar substrate. The first outer conductor layer is arranged in the form of a first planar outer conductor winding having a first and second end on or in the first outer ply. The second outer conductor layer is arranged in the form of a second planar outer conductor winding having a first and second end on or in the second outer ply. The first outer conductor layer and the second outer conductor layer are galvanically connected to each other, the respective first ends of the first and second outer conductor layers forming a first outer conductor terminal of the first transformation module terminal and the respective second ends of the first and second outer conductor layers forming a second outer conductor terminal of the first transformation module terminal. The transformation module further comprises an inner conductor having an inner conductor track arranged on or in the multi-ply planar substrate. The inner conductor track runs in a planar inner conductor winding, at least a first part of the planar inner conductor winding being arranged in the first intermediate ply and the inner conductor track being covered by the first outer conductor layer in a direction of the first outer ply and by the second outer conductor layer in a direction of the second outer ply. The inner conductor track comprises a first inner conductor end and a second inner conductor end, the first and second inner conductor ends forming the second transformation module terminal. The first and second planar outer conductor windings and the planar inner conductor winding are arranged so as to overlap each other in plan view, so that a predetermined electrical and magnetic coupling is established between the first and second planar outer conductor windings and the planar inner conductor winding. The transformation module further comprises an outer conductor connection arrangement arranged on or in the multi-ply planar substrate and galvanically connecting the first and second outer conductor layers to each other such that the outer conductor connection arrangement together with the first and second outer conductor layers forms an outer conductor casing which encloses the planar inner conductor winding of the inner conductor track of the inner conductor in an RF-tight manner.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows an exemplary embodiment of a transformation module in exploded view;

FIG. 2A shows an exemplary embodiment of a first outer ply;

FIG. 2B shows an exemplary embodiment of a first intermediate ply;

FIG. 2C shows an exemplary embodiment of a second intermediate ply;

FIG. 2D shows an exemplary embodiment of a second outer ply;

FIG. 3A shows an exemplary embodiment of the first intermediate ply;

FIG. 3B shows an exemplary embodiment of the first outer ply;

FIG. 4A shows an exemplary embodiment of the first or second outer ply;

FIG. 4B shows an exemplary embodiment of the first intermediate ply;

FIG. 5 shows an exemplary embodiment of an RF amplifier arrangement with the transformation module; and

FIG. 6 shows an exemplary embodiment of the arrangement for accelerating charged particles with at least one RF amplifier arrangement.

### DETAILED DESCRIPTION

In an embodiment, the present disclosure provides an impedance transformer which can be manufactured cheaply and reproducibly and has a compact design. At the same time, the assembly process in production should be as simple as possible.

The foregoing is achieved by a transformation module according to the present disclosure. An RF amplifier arrangement comprising such a transformation module is also disclosed. An arrangement for accelerating charged particles, which has at least one such RF amplifier arrangement is also disclosed.

The transformation module described here is used to transform a first input impedance at a first transformation module terminal to a second input impedance at a second transformation module terminal.

The transformation module is suitable, for example, for use in an RF amplifier arrangement, in particular in a push-pull amplifier arrangement.

Such an RF amplifier arrangement can be used, for example, in an arrangement for accelerating charged particles. “Charged particles” here refers to particles the size of atoms or molecules.

An arrangement for accelerating charged particles can refer to:
a plasma process for coating or etching or other material processing, in which ions are accelerated to achieve the process result, in particular also the excitation of gas lasers;
particle accelerators, such as linear particle accelerators (LINACs), cyclotrons, or similar accelerators of charged particles.

To significantly simplify manufacturing and handling, the transformation module has a multi-ply structure. For this purpose, a multi-ply planar substrate is provided, in particular in the form of a circuit board.

The multi-ply substrate has a first outer ply, a second outer ply and a first intermediate ply, with the first intermediate ply being arranged between the first and second outer plies.

An outer conductor having a first outer conductor layer and a second outer conductor layer is arranged on or in the substrate, wherein the first outer conductor layer is arranged in the form of a first planar outer conductor winding having a first and second end on or in the first outer ply and wherein the second outer conductor layer is arranged in the form of a second planar outer conductor winding having a first and second end on or in the second outer ply.

The first outer conductor layer and the second outer conductor layer are galvanically connected to each other, the respective first ends of the first and second outer conductor layers forming a first outer conductor terminal of the first transformation module terminal, and the respective second ends of the first and second outer conductor layers forming a second outer conductor terminal of the first transformation module terminal.

An inner conductor having an inner conductor track is arranged on or in the substrate. The inner conductor track runs in a planar inner conductor winding, and at least a first part of the planar inner conductor winding is arranged in the first intermediate ply and the inner conductor track is covered by the first outer conductor layer in the direction of the first outer ply and by the second outer conductor layer in the direction of the second outer ply.

The inner conductor track comprises a first inner conductor end and a second inner conductor end, with the two inner conductor ends forming the second transformation module terminal.

The first and second planar outer conductor windings and the planar inner conductor winding are arranged predominantly overlapping each other in plan view. This allows a predetermined electrical and magnetic coupling to be established between the first and second planar outer conductor windings and the planar inner conductor winding.

An outer conductor connection arrangement is arranged on or in the substrate and galvanically connects the first and second outer conductor layers to each other such that the outer conductor connection arrangement together with the first and second outer conductor layers forms an outer conductor casing which encloses the planar inner conductor winding of the inner conductor track of the inner conductor predominantly in an RF-tight manner.

In an aspect, the outer conductor connection arrangement is at least partially, preferably predominantly, arranged on an outer region of at least one of the following:
the planar substrate,
the first outer conductor layer or
the second outer conductor layer.

The outer region refers to the region of the outer edge of the device. That could be the outer margin. This can also be a region that lies within the outer margin, but in close proximity to it.

In an aspect, the transformation module comprises a multi-ply planar structure. Such a multi-ply planar structure can be produced particularly easily and reproducibly.

In an aspect, the inner conductor comprises a planar inner conductor winding and is arranged between the first outer conductor layer and the second outer conductor layer, the first outer conductor layer and the second outer conductor layer also being constructed respectively in the form of a first planar outer conductor winding and a second planar outer conductor winding. This allows the transformation ratio between the first transformation module terminal, with its first and second outer conductor terminals, and the second transformation module terminal, with its first and second inner conductor ends, to be set in a very clever way.

For example, if the first and second planar outer conductor windings each comprise exactly one loop extending around a center and the planar inner conductor winding comprises two loops extending around a center, then the transformation ratio is 1:4. If, on the other hand, the planar inner conductor winding comprises three loops extending around the center, the transformation ratio is 1:9.

To further improve the electrical properties, the substrate also comprises the outer conductor connection arrangement in an aspect. It is particularly advantageous here that the outer conductor connection arrangement galvanically connects the first and second outer conductor layers to each other, so that the planar inner conductor winding is enclosed by this galvanic connection. The planar inner conductor winding acts like an RF cage, preventing or severely limiting the coupling of electromagnetic waves from the outside into the planar inner conductor winding and thus preventing or severely limiting the escape of RF signals outwards on the planar inner conductor winding.

The wording according to which the outer conductor casing encloses the planar inner conductor winding of the inner conductor track “predominantly” in an RF-tight manner is to be understood as meaning that more than 50%, 60%, 70%, 80% or more than 90% of the area between the first and second outer conductor layers is shielded laterally by the outer conductor connection arrangement.

The transformation module can be operated in two directions. An RF signal can be applied to the first inner conductor end and/or to the second inner conductor end and thus to the second transformation module terminal. An RF signal can also be applied to the first outer conductor terminal and/or the second outer conductor terminal, and thus to the first transformation module terminal. The RF signal is then transformed and output at the other transformation module terminal. An RF signal is an electrical signal, in particular an electrical voltage relative to a fixed potential, such as a reference ground.

The term “in an RF-tight manner” means that RF fields cannot penetrate or escape or can only do so with significant attenuation. The field is therefore concentrated inside the transformation module and does not spread widely.

An “input impedance” is in particular to be understood as an impedance that is measured with an RF signal at a terminal relative to a fixed potential, e.g. ground. The impedance can have a real part and an imaginary part.

In an aspect, the circuit board is a PCB (printed circuit board).

In an aspect, the first outer conductor layer is a predetermined electrically conductive conductor track structure in the first outer ply. Additionally or alternatively, the second outer conductor layer is a predetermined electrically conductive conductor track structure in the second outer ply.

In an aspect, the inner conductor track is a predetermined electrically conductive conductor track structure in the first intermediate ply.

In an aspect, the planar inner conductor winding runs around a center in the first intermediate ply.

In an aspect, the planar inner conductor winding runs in at least one loop, 1.5 loops, 2 loops, 2.5 loops or in 3 loops around the center of the first intermediate ply.

In an aspect, the transformation module can be operated in a frequency range from 40 MHz to 400 MHz and in particular in a frequency range from 100 MHz to 200 MHz. This makes it possible in particular to address frequency ranges that are difficult or impossible to reach using ferrites or microstrip structures.

In an aspect, the inner conductor track has a width that is smaller than the width of the first and second outer conductor layers. This ensures that the inner conductor track is particularly well enclosed by the first and second outer conductor layers in an RF-tight manner. In particular, the width of the inner conductor track over the entire length of the inner conductor track or over the predominant length of the inner track or over at least the first part of the planar inner conductor winding is smaller than the width of the first and second outer conductor layers.

In an aspect, the first outer ply is an external ply on the substrate, in particular on the circuit board. Additionally or alternatively, the second outer ply is an external ply on the substrate, in particular on the circuit board.

In an aspect, the first outer ply is partially or completely covered by dielectric insulation. In this case, the first outer conductor layer is completely or partially covered by such dielectric insulation. There can also be further plies applied to the first outer ply. Alternatively, the first outer ply is free or predominantly free of such dielectric insulation. In this case, the first outer conductor layer is not, or predominantly not, covered by such dielectric insulation.

In an aspect, the second outer ply is partially or completely covered by dielectric insulation. In this case, the second outer conductor layer is completely or partially covered by such dielectric insulation. There can also be further plies applied to the second outer ply. Alternatively, the second outer ply is free or predominantly free of such dielectric insulation. In this case, the second outer conductor layer is not, or predominantly not, covered by such dielectric insulation.

In an aspect, the first outer conductor layer is designed as a planar metallization layer and is free or predominantly free of cutouts in this metallization layer. Alternatively, the first outer conductor layer is designed as a metallization layer with such cutouts, so that the metallization layer has a linear and/or grid structure.

In an aspect, the second outer conductor layer is designed as a planar metallization layer and is free or predominantly free of cutouts in this metallization layer. Alternatively, the second outer conductor layer is designed as a metallization layer with such cutouts, so that the metallization layer has a linear and/or grid structure.

In an aspect, the first outer conductor layer is rectangular, square, elliptical or round in plan view. Additionally or alternatively, the second outer conductor layer is rectangular, square, elliptical or round in plan view.

In an aspect, the first outer conductor layer and the second outer conductor layer enclose respective centers on the first and second outer plies, thereby forming the first planar outer conductor winding and the second planar outer conductor winding.

In an aspect, the first outer conductor layer and the second outer conductor layer have the same shape in plan view or the shapes differ from each other by less than 10%. In particular, a deviation in overlap in plan view is less than 10% of the area of the first or second outer conductor layer.

In an aspect, the first planar outer conductor winding is separated by a gap, thus forming the first and second ends. Furthermore, the second planar outer conductor winding is separated by a gap, thus forming the first and second ends.

In an aspect, the gap runs along a straight line and is free of angles and curves.

In an aspect, the gap of the first outer conductor layer and the gap of the second outer conductor layer are arranged so as to overlap or predominantly overlap each other in plan view.

In an aspect, in plan view, the first part of the planar inner conductor winding crosses the gap of the first or second outer conductor layer at an angle that is perpendicular in an aspect on the first intermediate ply.

In an aspect, the first outer conductor layer is axially symmetrical with respect to a longitudinal axis that runs through the gap in the first outer conductor layer. Additionally or alternatively, the second outer conductor layer is axially symmetrical with respect to a longitudinal axis that runs through the gap in the second outer conductor layer.

In an aspect, the transformation module comprises a power supply terminal, in particular a DC voltage terminal.

The supply terminal can be connected in particular to the first and/or second outer conductor layer at a feed-in point. The feed-in point can be arranged in a way that is in particular opposite the gap. In particular, a straight line that runs through the gap can also run through the feed-in point.

In the case of an axially symmetrical structure of the first outer conductor layer and/or second outer conductor layer, the longitudinal axis can run through the corresponding feed-in point. This results in a symmetrical feed. The DC voltage can be used to supply the RF amplifier arrangement.

In an aspect, the substrate comprises a second intermediate ply, with the first intermediate ply and the second intermediate ply being arranged between the first and second outer plies.

The inner conductor track can also be arranged on the second intermediate ply. The first intermediate ply and the second intermediate ply can be arranged in particular one on top of the other. The advantage of a second intermediate ply, and thus preferably a total of four plies arranged one above the other, is that a circuit board with four layers can be pressed symmetrically and the production of such a printed circuit board is cheaper than if only three plies are used.

In an aspect, the inner conductor track is a predetermined electrically conductive conductor track structure in the second intermediate ply.

In an aspect, a dielectric material is introduced between the first intermediate ply and the second intermediate ply.

In an aspect, the substrate comprises a via through which the inner conductor track transitions from the first intermediate ply to the second intermediate ply. The via can penetrate the entire substrate or only a part of the substrate, e.g. the first and second intermediate plies.

In an aspect, at least a second part of the planar inner conductor winding is arranged in the second intermediate ply. In particular, the inner conductor track, in particular the second part of the planar inner conductor winding, is covered by the first outer conductor layer in the direction of the first outer ply and by the second outer conductor layer in the direction of the second outer ply. By using such a second intermediate ply, a higher transformation ratio can be achieved while maintaining a compact structure of the transformation module.

In an aspect, the first part of the planar inner conductor winding has the same number of loops as the second part of the planar inner conductor winding. For example, the first part of the planar inner conductor winding can comprise a loop, and the second part of the planar inner conductor winding can also comprise a loop. In total, this results in two loops, which gives a transformation ratio of 1:4, assuming that the first and second planar outer conductor windings also each comprise a loop. Preferably, the first part of the planar inner conductor winding has 1.5 loops and the second part of the planar inner conductor winding also has 1.5 loops. In total, this results in three loops, resulting in a transformation ratio of 1:9.

In an aspect, the first part of the planar inner conductor winding on the first intermediate ply runs in the same direction, in particular around a center on the first intermediate ply, as the second part of the planar inner conductor winding on the second intermediate ply, which runs around a center on the second intermediate ply. For example, the first part and the second part run clockwise or counterclockwise.

In an aspect, a first part of the planar inner conductor winding on the first intermediate ply is only partially overlapping with a second part of the planar inner conductor winding on the second intermediate ply in plan view. This reduces the capacitive coupling between the first part and the second part, which has a positive effect on the electrical properties of the transformation module.

In an aspect, the substrate comprises a via through which the inner conductor track transitions from the first intermediate ply to the first or second outer ply. In this case, preferably no second intermediate ply is necessary.

In an aspect, a second part of the planar inner conductor winding runs partially or completely through the gap of the first or second outer conductor layer on the first or second outer ply.

In an aspect, in a first alternative, the second part of the planar inner conductor winding runs further on the first or second outer ply.

In an aspect, or in a second alternative, the second part of the planar inner conductor winding transitions via a further via from the first or second outer ply back to the first intermediate ply. There, it can run further apart around a center of the first intermediate ply than directly before the transition into the first or second outer ply or than the first part directly before the transition into the first or second outer ply. This makes it possible for the inner conductor to be guided out of the intermediate ply again, so that both the first inner conductor end and the second inner conductor end are available as terminals. In principle, the inner conductor should remain in the intermediate ply for as long as possible, because it is shielded in the intermediate ply by the first outer conductor layer and the second outer conductor layer.

In an aspect, the first inner conductor end and the second inner conductor end of the inner conductor track are arranged on the same side of the substrate. This makes connection particularly easy.

In an aspect, the first inner conductor end and/or the second inner conductor end protrude laterally over the first and/or second outer conductor layer, in plan view of the first and/or second outer conductor layer, thus enabling easy connection.

In an aspect, an edge of the substrate, on which the first inner conductor end and/or the second inner conductor end are arranged, is metallized, in particular electroplated, whereby the first inner conductor end and/or the second inner conductor end can be soldered to a further circuit board of the RF amplifier arrangement in an SMD process.

In an aspect, the outer conductor connection arrangement comprises a plurality of vias that galvanically connect the first outer conductor layer to the second outer conductor layer. These vias then form the outer conductor casing. Additionally or alternatively, the outer conductor connection arrangement comprises an electrically conductive connection, in particular an electroplating, which is arranged at the edge of the substrate and galvanically connects the first outer conductor layer to the second outer conductor layer. This electrically conductive connection then forms the outer conductor casing.

In an aspect, the electrically conductive connection along the edge is predominantly closed.

In an aspect, the vias are arranged with a distance between them that is smaller than λ/4 or λ/10, where λ is the wavelength of the frequency, in particular the center frequency of an RF signal, which is transmitted via the transformation module.

In an aspect, the plurality of vias follow an inner and an outer boundary line, with the inner conductor running between the inner and the outer boundary line, thus providing electromagnetic shielding for the inner conductor track in this region. The inner boundary line is located closer to the center of the substrate than the outer boundary line.

In an aspect, the outer boundary line can run along the edge region of the substrate or be spaced from it.

In an aspect, the vias can only be introduced in the region of the first and second outer plies, where the first and second outer conductor layers are located.

In an aspect, the plurality of vias can follow an inner boundary line.

In an aspect, the edge of the substrate can be provided with the electrically conductive connection, in particular an electroplating, with the inner conductor track running between the inner boundary line and the electrically conductive connection, thereby electromagnetically shielding the inner conductor track in this region. In this case, both vias and an electrical connection, in particular in the form of electroplating, are used.

In an aspect, the substrate comprises a cutout in its center, thus forming an inner edge.

In an aspect, the outer conductor connection arrangement can have an internal electrically conductive connection, in particular in the form of electroplating, which is formed at the inner edge.

In an aspect, the inner conductor track can run between the inner electrically conductive connection at the inner edge and the electrically conductive connection at the outer edge, thus providing electromagnetic shielding for the inner conductor track in this region.

In an aspect, the outer conductor connection arrangement comprises at least one gap.

In an aspect, the inner conductor track can emerge from at least one gap in order to transition from the first intermediate ply into another ply, e.g. the second intermediate ply or first or second outer ply. The gap in the outer ply can therefore be used to guide part of the inner conductor track. This can be used to advantage to reduce plies and only route crossings of the inner conductor track in an outer ply. Additionally or alternatively, the inner conductor track emerges with its first and second inner conductor ends from the at least one gap. Basically, there can be two gaps spaced apart, with the inner conductor track emerging with its first inner conductor end from the first gap and with its second inner conductor end from the second gap.

In an aspect, the substrate comprises a plurality of additional vias, with the additional vias galvanically connecting the first outer conductor layer to the second outer conductor layer. The additional vias run between two loops of the planar inner conductor winding of the inner conductor track. This results in improved decoupling between two loops of the inner conductor track. The two loops can be arranged on the same ply or on different plies. Plies can also be intermediate plies. In addition to or as an alternative to the additional vias, an additional electrically conductive connection, in particular electroplating, can also be used. To introduce this additional electrically conductive connection, the substrate would have to be milled accordingly.

In an aspect, an RF signal can be supplied or output at the first inner conductor end. Preferably, the second inner conductor end can be connected to a fixed potential, in particular a reference ground. In this context, the second transformation module terminal of the transformation module is preferably a single-ended terminal.

In an aspect, the first transformation module terminal of the transformation module is a differential terminal, wherein a first RF signal of a differential RF signal can be output or supplied at the first ends of the first and second outer conductor layers, and wherein a second RF signal of the differential RF signal can be output or supplied at the second ends of the first and second outer conductor layers.

The second transformation module terminal of the transformation module can also be a differential terminal. In this context, the first transformation module terminal of the transformation module can be a single-ended terminal.

In an aspect, the first planar outer conductor winding and the second planar outer conductor winding are galvanically isolated from the planar inner conductor winding.

In an aspect, the first planar outer conductor winding and the second planar outer conductor winding are each formed in one piece.

The RF amplifier arrangement described here is designed in particular in the form of a push-pull amplifier arrangement. The RF amplifier arrangement comprises, in an aspect, a first transistor, a second transistor and an already described transformation module.

The RF amplifier arrangement can, in an aspect, have a signal input to which an RF signal to be amplified can be applied, wherein the signal input is connected to the first inner conductor end of the inner conductor track.

The second inner conductor end of the inner conductor track is connected to a reference ground in an aspect.

In an aspect, the respective first ends of the first and second outer conductor layers are connected via a first connection to a gate terminal of the first transistor.

In an aspect, the respective second ends of the first and second outer conductor layers are connected via a second connection to a gate terminal of the second transistor. In this use case, a single-ended terminal can be transformed into a differential terminal.

In an aspect, the transformation module can be designed for high power, in particular greater than or equal to 200 W, and in particular be designed for connection to the output of an above-described RF amplifier arrangement. In this way, the differential outputs of an RF amplifier arrangement can be formed into an asymmetric output, and one terminal can be connected to a reference ground and the other terminal can be connected as an RF signal to a load.

In an aspect, the RF amplifier arrangement comprises a supply input that is connected to a supply terminal on the first and/or second outer conductor layer of the transformation module. The first transistor and the second transistor can be supplied with energy via this supply input.

In an aspect, the transformation module is arranged on a circuit board of the RF amplifier arrangement and in particular soldered to the circuit board via a soldering process, such as a reflow process. A bonding process and/or an electrically conductive adhesive can also be used for the electrical connection of the transformation module to the circuit board of the RF amplifier arrangement. Alternatively, the transformation module can be directly part of the circuit board of the RF amplifier arrangement.

In an aspect, a first impedance matching circuit is arranged in the first connection to transform the input impedance at the first outer conductor terminal of the first transformation module terminal to an input impedance of the first transistor. Furthermore, a second impedance matching circuit is arranged in the second connection to transform the input impedance at the second outer conductor terminal of the first transformation module terminal of the transformation module to an input impedance of the second transistor.

In an aspect, the input impedance at the first outer conductor terminal of the first transformation module terminal is higher than the input impedance of the first transistor. Furthermore, the input impedance at the second outer conductor terminal of the first transformation module terminal is greater than the input impedance of the second transistor.

In an aspect, the input impedance of the first and second transistors is only a few ohms, in particular less than 10 ohms.

In an aspect, the first impedance matching circuit comprises at least one inductor, such as a coil, and at least one capacitor.

In an aspect, the second impedance matching circuit comprises at least one inductor, such as a coil, and at least one capacitor.

In an aspect, the transformation ratio of the first impedance matching circuit and the second impedance matching circuit remains constant during operation. Alternatively, the transformation ratio of the first impedance matching circuit and the second impedance matching circuit can be changed during operation by switching reactances, such as inductors or capacitors, on and off.

In an aspect, this switching on and off is done via semiconductor switches, which also include PIN diodes.

The arrangement for accelerating charged particles, in particular in the form of a particle accelerator, comprises, in an aspect, at least one already described RF amplifier arrangement. Accelerating charged particles is not only necessary in a particle accelerator, but can also be used in a plasma process. In a plasma process, charged atoms are accelerated. This allows, for example, industrial plasma coating processes, etching processes or gas laser excitation to be carried out.

In an aspect, the arrangement for accelerating charged particles comprises at least one RF resonator. The at least one RF amplifier arrangement is connected to the at least one RF resonator for transmitting the amplified RF signal.

The development is described below purely by way of example with reference to the drawings.

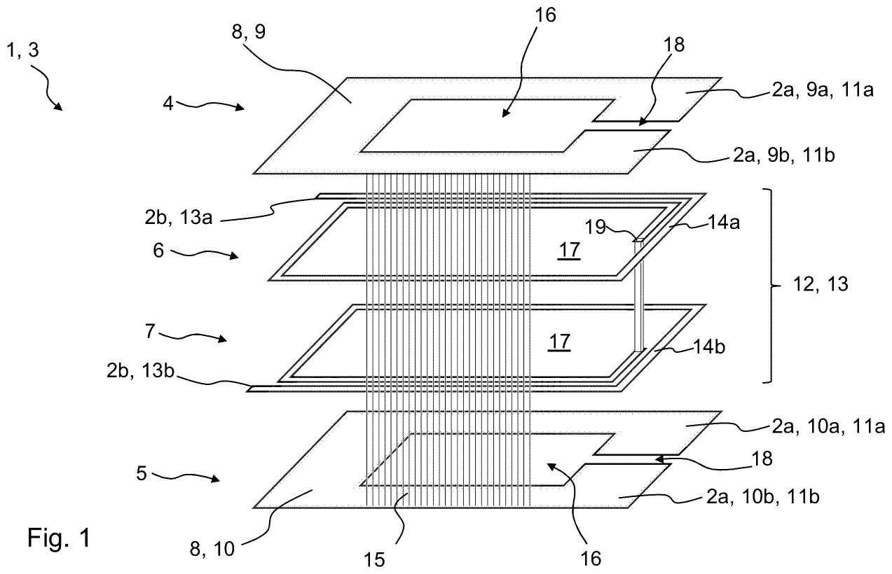

FIG. 1 shows an exemplary embodiment of a transformation module 1. The transformation module 1 serves to transform a first input impedance at a first transformation module terminal 2a to a second input impedance at a second transformation module terminal 2b for use in an RF amplifier arrangement 50, in particular a push-pull amplifier arrangement, preferably for an arrangement 100 for accelerating charged particles, wherein the transformation module 1 has a multi-ply structure.

The transformation module 1 comprises a multi-ply planar substrate 3. The substrate 3 has a first outer ply 4, a second outer ply 5, a first intermediate ply 6 and, in this case, a second intermediate ply 7. The substrate 3 also includes dielectric layers.

An outer conductor 8 having a first outer conductor layer 9 and a second outer conductor layer 10 is arranged on or in the substrate 3, wherein the first outer conductor layer 9 is arranged in the form of a first planar outer conductor winding having a first end 9a and second end 9b on or in the first outer ply 4 and wherein the second outer conductor layer 10 is arranged in the form of a second planar outer conductor winding having a first end 10a and a second end 10b on or in the second outer ply 5. The first and second outer conductor layers 9, 10 are arranged parallel but spaced apart from each other. The first and second outer conductor layers 9, 10 are electrically conductive.

The first outer conductor layer 9 and the second outer conductor layer 10 are galvanically connected to each other, the respective first ends 9a, 10a of the first and second outer conductor layers 9, 10 forming a first outer conductor terminal 11a of the first transformation module terminal 2a and the respective second ends 9b, 10b of the first and second outer conductor layers 9, 10 forming a second outer conductor terminal 11b of the first transformation module terminal 2a.

Furthermore, an inner conductor 12 with an inner conductor track 13 is arranged on or in the substrate. The inner conductor track 13 runs in a planar inner conductor winding, at least a first part 14a of the planar inner conductor winding being arranged in the first intermediate ply 6 and the inner conductor track 13 being covered in the direction of the first outer ply 4 by the first outer conductor layer 9 and in the direction of the second outer ply 5 by the second outer conductor layer 10. A second part 14b of the planar inner conductor winding is arranged in the second intermediate ply 7. The inner conductor 12 with its inner conductor track 13 is electrically conductive.

The inner conductor track 13 comprises a first inner conductor end 13a and a second inner conductor end 13b, with the two inner conductor ends 13a, 13b forming the second transformation module terminal 2b. The first inner conductor end 13a is arranged on the first intermediate ply 6 and the second inner conductor end 13b is arranged on the second intermediate ply 7.

The first and second planar outer conductor windings and the planar inner conductor winding are arranged so as to predominantly overlap each other in plan view, so that a predetermined electrical and magnetic coupling is established between the first and second planar outer conductor windings and the planar inner conductor winding.

An outer conductor connection arrangement 15 is arranged on or in the substrate 3 and galvanically connects the first outer conductor layer 9 and the second outer conductor layer 10 to each other such that the outer conductor connection arrangement 15 together with the first outer conductor layer 9 and the second outer conductor layer 10 forms an outer conductor casing that encloses the planar inner conductor winding of the inner conductor track 13 of the inner conductor 12 predominantly in an RF-tight manner.

The outer conductor connection arrangement 15 is arranged here on the outer region of the first outer conductor layer 9 and the second outer conductor layer 10. Substrate 3 can have dimensions as large as the first outer conductor layer 9 or the second outer conductor layer 10. This would mean that the outer conductor connection arrangement 15 would also be arranged at the outer region of the substrate 3.

The outer conductor connection arrangement 15 is shown here in such a way that it is only partially arranged on the outer region of the first outer conductor layer 9 and the second outer conductor layer 10. This description is intended to provide clarity. The outer conductor connection arrangement 15 can be arranged around a large part or also almost completely on the outer region of the first outer conductor layer 9 and the second outer conductor layer 10 or of the substrate 3.

In this case, the inner conductor track 13 of the inner conductor 12 has a width that is smaller than the width of the first and second outer conductor layers 9, 10.

The first outer conductor layer 9, with its first planar outer conductor winding, encloses a center 16 of the first outer ply 4. The first outer conductor layer 9 runs with the first planar outer conductor winding in a loop around the center 16 of the first outer ply 4. The second outer conductor layer 10, with its second planar outer conductor winding, encloses a center 16 of the second outer ply 5. The second outer conductor layer 10 runs with the second planar outer conductor winding in a loop around the center 16 of the second outer ply 5. The first part 14a of the inner conductor track 13 encloses a center 17 of the first intermediate ply 6. The first part 14a of the inner conductor track 13 runs in 1.5 loops around the center 17 of the first intermediate ply 6. The second part 14b of the inner conductor track 13 encloses a center 17 of the second intermediate ply 7. The second part 14 b of the inner conductor track 13 runs in 1.5 loops around the center 17 of the second intermediate ply 7. This results in an overall transformation ratio of 1:9. In this case, the first part 14 a of the planar inner conductor winding of the inner conductor track 13 has the same number of loops as the second part 14b of the planar inner conductor winding of the inner conductor track 13.

The first planar outer conductor winding of the first outer conductor layer 9 is separated by a gap 18, forming the first and second ends 9a, 9b. The second planar outer conductor winding of the second outer conductor layer 10 is separated by a gap 18, forming the first and second ends 10a, 10b. In this case, the gaps 18 of the first and second outer conductor layers 9, 10 are arranged so as to overlap each other in plan view.

In plan view of the gap 18 of the first or second outer conductor layer 9, 10, the first and/or second part 14a, 14b of the planar inner conductor winding of the inner conductor 13 crosses the gap 18 of the first or second outer conductor layer 9, 10 at a right angle on the first or second intermediate ply 6, 7. The angle here is right-angled, but of course it does not necessarily have to be. Angles in a range of 45-90° are also suitable, with the 90° angle being the most suitable.

The first part 14a of the planar inner conductor winding of the inner conductor 13 runs on the first intermediate ply 6 in the same direction as the second part 14b of the planar inner conductor winding of the inner conductor 13 on the second intermediate ply 7. In this case, both the first part 14a and the second part run clockwise around the center 17.

The substrate 3 comprises a via 19 through which the inner conductor track 13 transitions from the first intermediate ply 6 to the second intermediate ply 7. The transition from the first part 14a to the second part 14b of the planar inner conductor winding of the inner conductor 13 then takes place at or in the region of the via 19.

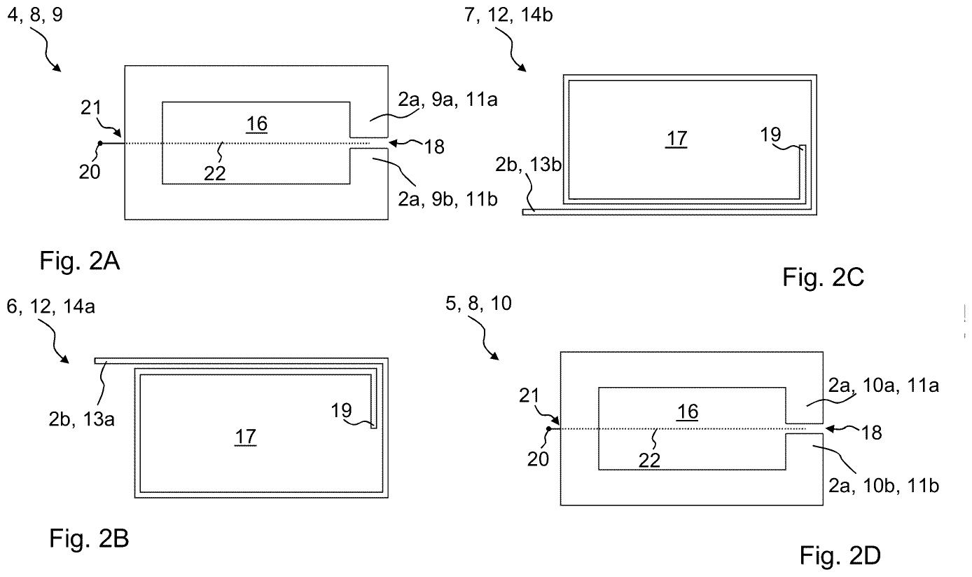

FIG. 2A shows a plan view of the first outer ply 4 with the first outer conductor layer 9 of the outer conductor 8 from FIG. 1. In plan view, the first outer conductor layer 9 is rectangular. The transformation module 1 also comprises a supply terminal 20, in particular in the form of a DC voltage terminal. The supply terminal 20 is connected to the first outer conductor layer 9 at a feed-in point 21, the feed-in point 21 being arranged opposite the gap 18, whereby a straight line 22, which runs through the gap 18, also runs through the feed-in point 21.

FIG. 2B shows a plan view of the first part 14a of the planar inner conductor winding of the inner conductor track 13 of the inner conductor 12 from FIG. 1. The first part 14 a extends with 1.5 loops around the center 17 of the first intermediate ply 6.

FIG. 2C shows a plan view of the second part 14b of the planar inner conductor winding of the inner conductor track 13 of the inner conductor 12 from FIG. 1. The second part 14 b extends with 1.5 loops around the center 17 of the second intermediate ply 7.

FIG. 2D shows a plan view of the second outer ply 5 with the second outer conductor layer 10 of the outer conductor 8 from FIG. 1. In plan view, the second outer conductor layer 10 is rectangular. The transformation module 1 also comprises a supply terminal 20, in particular in the form of a DC voltage terminal. The supply terminal 20 is connected to the second outer conductor layer 10 at a feed-in point 21, the feed-in point 21 being arranged opposite the gap 18, whereby a straight line 22, which runs through the gap 18, also runs through the feed-in point 21.

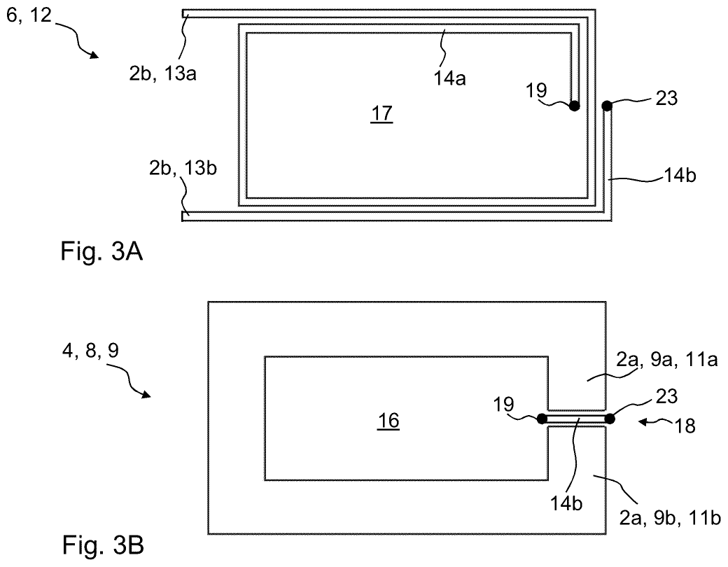

FIGS. 3A and 3B show an exemplary embodiment of the transformation module 1, wherein the substrate 3 comprises only the first intermediate ply 6 together with the first and second outer plies 4, 5. The substrate 3 comprises the via 19 through which the inner conductor track 13 transitions from the first intermediate ply 6 to the first outer ply 4. It could also transition to the second outer ply 5. A second part 14b of the planar inner conductor winding of the inner conductor track 13 runs partially or completely through the gap 18 of the first outer conductor layer 9 on the first outer ply 4, and the second part 14b of the planar inner conductor winding of the inner conductor track 13 transitions from the first outer ply 4 back to the first intermediate ply 6 via a further via 23, but preferably runs further spaced from the center 17 of the first intermediate ply 6 than directly before the transition into the first outer ply 4 or than the first part 14a of the planar inner conductor winding of the inner conductor track 13 directly before the transition into the first outer ply 4. In this way, the inner conductor 12 is also guided out of the first intermediate ply 6 again. In this case, both the first inner conductor end 13a and the second inner conductor end 13b of the inner conductor 12 bear against the first intermediate ply 6. Furthermore, the first inner conductor end 13a and the second inner conductor end 13b of the inner conductor track 13 are arranged on the same side of the substrate 3. In this case, the first part 14a comprises 1.5 loops and the second part 0.5 loops, whereby the inner conductor 12 runs in a total of 2 loops around the center 17 of the first and second intermediate plies 6, 7. Therefore, a transformation ratio of 1:4 is achieved.

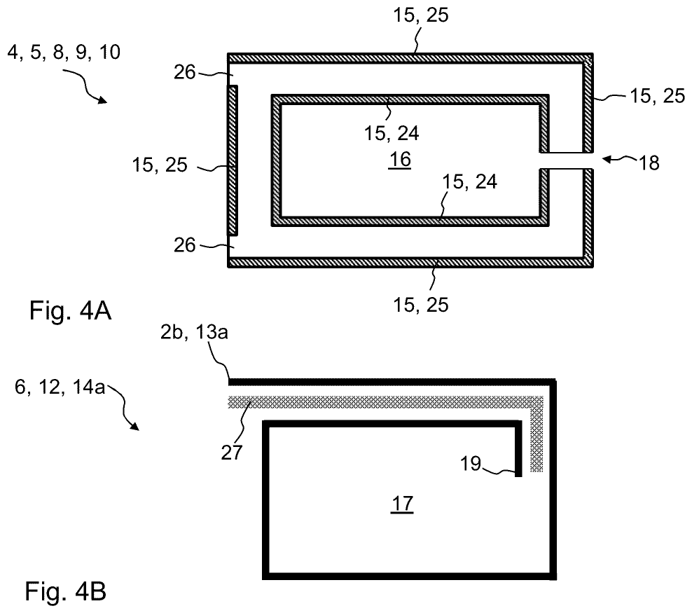

FIG. 4A shows a further exemplary embodiment of the first and/or second outer ply 4, 5. The hatched area shows the outer conductor connection arrangement 15. The outer conductor connection arrangement 15 comprises a plurality of vias that galvanically connect the first outer conductor layer 9 to the second outer conductor layer 10. Additionally or alternatively, the outer conductor connection arrangement 15 comprises an electrically conductive connection, in particular an electroplating, which is arranged at the edge of the substrate 3 and galvanically connects the first outer conductor layer 9 to the second outer conductor layer 10.

Preferably, the plurality of vias of the outer conductor connection arrangement 15 follow an inner boundary line 24 and an outer boundary line 25, with the inner conductor track 13 running between the inner and the outer boundary lines 24, 25, thereby electromagnetically shielding the inner conductor track 13 in this region. The outer conductor connection arrangement 15 comprises at least two gaps 26, which are spaced apart from each other at the edge of the substrate 3. The inner conductor track 13 emerges with its first and second inner conductor ends 13a, 13b from these gaps 26 on the first intermediate ply 6 and the optional second intermediate ply 7. There are no vias between the first and second outer plies 4, 5 at the gaps 26.

FIG. 4B shows a further exemplary embodiment of the first intermediate ply 6 with the first part 14a of the inner conductor track 13 of the inner conductor 12. In this case, the substrate 3 comprises a plurality of additional vias 27, wherein the additional vias 27 galvanically connect the first outer conductor layer 9 to the second outer conductor layer 10 and thereby also run through the first intermediate ply 6 and the optional second intermediate ply 7. The additional vias 27 run between two loops of the first part 14a of the planar inner conductor winding of the inner conductor track 13. This optimally decouples these two loops from each other.

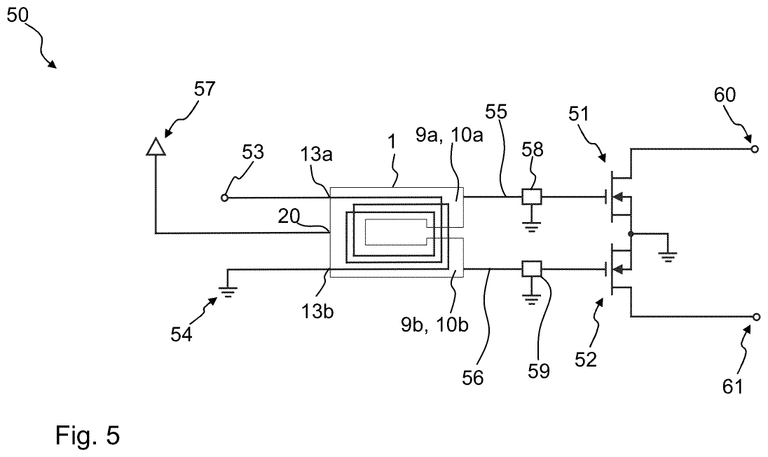

FIG. 5 shows the RF amplifier arrangement 50, in particular in the form of a push-pull amplifier arrangement, with a first transistor 51, a second transistor 52 and the transformation module 1. The RF amplifier arrangement 50 comprises a signal input 53 to which an RF signal to be amplified can be applied, the signal input 53 being connected to the first inner conductor end 13a of the inner conductor track 13 of the inner conductor 12. The second inner conductor end 13b of the inner conductor track 13 of the inner conductor 12 is connected to a reference ground 54. The respective first ends 9a, 10a of the first and second outer conductor layers 9, 10 are connected via a first connection 55 to a gate terminal of the first transistor 51. The respective second ends 9b, 10b of the first and second outer conductor layers 9, 10 are connected via a second connection 56 to a gate terminal of the second transistor 52.

The RF amplifier arrangement 50 comprises a supply input 57 which is connected to a supply terminal 20 on the first and/or second outer conductor layer 9, 10 of the transformation module 1. A DC voltage is preferably provided to the supply input 57 to supply the first and second transistors 51, 52.

The RF amplifier arrangement 50 comprises a first impedance matching circuit 58 to transform the input impedance at the first outer conductor terminal 11a of the first transformation module terminal 2a of the transformation module 1 to an input impedance of the first transistor 51. To this end, the first impedance matching circuit 58 comprises corresponding capacitors and inductors. The first impedance matching circuit 58 is arranged in the first connection 55.

The RF amplifier arrangement 50 further comprises a second impedance matching circuit 59 to transform the input impedance at the second outer conductor terminal 11b of the first transformation module terminal 2a of the transformation module 1 to an input impedance of the second transistor 52. To this end, the second impedance matching circuit 59 comprises corresponding capacitors and inductors. The second impedance matching circuit 59 is arranged in the second connection 56.

Furthermore, the emitter terminals of the first and second transistors 51, 52 are preferably connected to a reference ground. A first signal output 60 is connected to the collector terminal of the first transistor 51. A second signal output 61 is connected to the collector terminal of the second transistor 52.

A transformation module can also be designed for high power, in particular greater than or equal to 200 W, and in particular be designed for connection to the first signal output 60 and to the second signal output 61 of an RF amplifier arrangement 50 as described above.

Thus, the differential signal outputs 60, 61 of an RF amplifier arrangement 50 can be formed into an asymmetric output between an RF power signal with the above-described high power, in particular greater than or equal to 200 W, in which one terminal can be on a reference ground 54 and the other terminal can be connected as an RF signal to a load.

Specifically, a correspondingly designed transformation module 1 can be connected with its first ends 9a, 10a to the first signal output 60 and with its second ends 9b, 10b to the second signal output 61.

In this case also, the supply terminal 20 can preferably be used to provide a DC supply to the RF amplifier arrangement 50.

The inner conductor 12 can be connected via its first inner conductor end 13a as an RF signal to a load.

The inner conductor 12 can be connected via its second inner conductor end 13b to a reference ground.

This allows the load to be operated between the RF power signal and reference ground, as is usually desired.

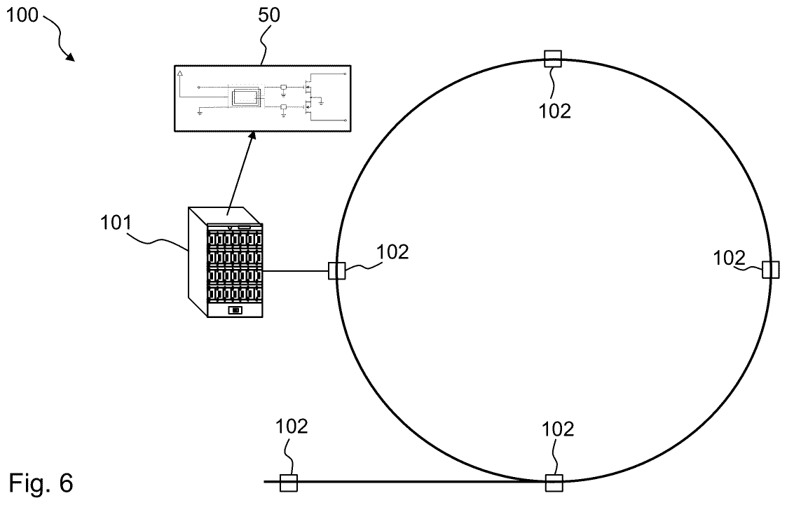

FIG. 6 shows an arrangement 100 for accelerating charged particles, in particular in the form of a particle accelerator. In this case, the arrangement 100 comprises a plurality of RF amplifier arrangements 50, which are arranged in a rack system 101. The arrangement 100 comprises a plurality of RF resonators 102. The RF resonators 102 are preferably connected to the first and second signal outputs 60, 61 of the RF amplifier arrangement 50.

The present disclosure is not limited to the described exemplary embodiments. During development, all described and/or drawn features can be combined as desired, unless otherwise stated.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A transformation module for transforming a first input impedance at a first transformation module terminal to a second input impedance at a second transformation module terminal for use in an RF amplifier arrangement, in particular a push-pull amplifier arrangement, preferably for an arrangement for accelerating charged particles, wherein the transformation module has a multi-ply structure, the transformation module comprising:
a multi-ply planar substrate, in particular a circuit board, having a first outer ply, a second outer ply and a first intermediate ply which is arranged between the first and second outer plies;
an outer conductor having a first outer conductor layer and a second outer conductor layer arranged on or in the multi-ply planar substrate, wherein the first outer conductor layer is arranged in the form of a first planar outer conductor winding having a first and second end on or in the first outer ply, and wherein the second outer conductor layer is arranged in the form of a second planar outer conductor winding having a first and second end on or in the second outer ply,
wherein the first outer conductor layer and the second outer conductor layer are galvanically connected to each other, the respective first ends of the first and second outer conductor layers forming a first outer conductor terminal of the first transformation module terminal and the respective second ends of the first and second outer conductor layers forming a second outer conductor terminal of the first transformation module terminal;
an inner conductor having an inner conductor track arranged on or in the multi-ply planar substrate,
wherein the inner conductor track runs in a planar inner conductor winding, at least a first part of the planar inner conductor winding being arranged in the first intermediate ply and the inner conductor track being covered by the first outer conductor layer in a direction of the first outer ply and by the second outer conductor layer in a direction of the second outer ply,
wherein the inner conductor track comprises a first inner conductor end and a second inner conductor end, the first and second inner conductor ends forming the second transformation module terminal,
wherein the first and second planar outer conductor windings and the planar inner conductor winding are arranged so as to predominantly overlap each other in plan view, so that a predetermined electrical and magnetic coupling is established between the first and second planar outer conductor windings and the planar inner conductor winding; and
an outer conductor connection arrangement arranged on or in the multi-ply planar substrate and galvanically connecting the first and second outer conductor layers to each other such that the outer conductor connection arrangement together with the first and second outer conductor layers forms an outer conductor casing which encloses the planar inner conductor winding of the inner conductor track of the inner conductor predominantly in an RF-tight manner.

2. The transformation module according to claim 1,
wherein the outer conductor connection arrangement is arranged at least partially, preferably predominantly, on an outer region of at least one of the following:
the multi-ply planar substrate,
the first outer conductor layer or
the second outer conductor layer.

3. The transformation module according to claim 1,
wherein the transformation module can be operated in a frequency range from 40 MHz to 400 MHz and in particular in a frequency range from 100 MHz to 200 MHz.

4. The transformation module according to claim 1,
wherein the inner conductor track has a width that is smaller than the width of the first and second outer conductor layers.

5. The transformation module according to claim 1,
wherein the multi-ply planar substrate comprises a second intermediate ply, wherein the first intermediate ply and the second intermediate ply are arranged between the first and second outer plies, and
wherein the inner conductor track is also arranged on the second intermediate ply.

6. The transformation module according to claim 5,
wherein the multi-ply planar substrate comprises a via through which the inner conductor track transitions from the first intermediate ply to the second intermediate ply.

7. The transformation module according to claim 5,
wherein at least a second part of the planar inner conductor winding of the inner conductor track is arranged in the second intermediate ply, the inner conductor track being covered by the first outer conductor layer in a direction of the first outer ply and by the second outer conductor layer in a direction of the second outer ply.

8. The transformation module according to claim 1,
wherein the first inner conductor end and the second inner conductor end of the inner conductor track are arranged on the same side on the multi-ply planar substrate.

9. The transformation module according to claim 1,
wherein the outer conductor connection arrangement comprises a plurality of vias that galvanically connect the first outer conductor layer to the second outer conductor layer, and/or
wherein the outer conductor connection arrangement comprises an electrically conductive connection, in particular an electroplating, which is arranged at an edge of the multi-ply planar substrate and galvanically connects the first outer conductor layer to the second outer conductor layer.

10. An RF amplifier arrangement, in particular in the form of a push-pull amplifier arrangement, comprising:
a first transistor;
a second transistor;
the transformation module according to claim 1;
a signal input to which an RF signal to be amplified can be applied, the signal input being connected to the first inner conductor end of the inner conductor track,
wherein the second inner conductor end of the inner conductor track is connected to a reference ground,
wherein the respective first ends of the first and second outer conductor layers are connected via a first connection to a gate terminal of the first transistor, and
wherein the respective second ends of the first and second outer conductor layers are connected via a second connection to a gate terminal of the second transistor.

11. The RF amplifier arrangement according to claim 10,
further comprising a supply input which is connected to a supply terminal on the first and/or second outer conductor layer of the transformation module.

12. An arrangement for accelerating charged particles, in particular in the form of a particle accelerator, wherein the arrangement has at least one RF amplifier arrangement according to claim 10.
